(19) United States
(12) Patent Application Publication
(10) Pub. No.: US 2009/0269506 A1
(43) Pub. Date: Oct. 29, 2009

(54) Method and apparatus for cleaning of a CVD reactor

(76) Inventor: Seiji Okura, Tokyo (JP)

Correspondence Address: Snell & Wilmer L.L.P. (ASM Japan), One Arizona Center, 400 East Van Buren Street, Phoenix, AZ, 85004-2202, US

(21) Appl. No.: 12/148,956

(22) Filed: Apr. 24, 2008

(51) Int. Cl. C23C 14/58; B08B 6/00; C25F 1/00

(52) U.S. Cl. 427/534; 134/1.1; 134/201

(57) ABSTRACT

The present invention provides a process and an apparatus for remote plasma cleaning of a process chamber of a chemical vapor deposition (CVD) reactor. The reactive species are generated in a remote plasma unit and are introduced into the process chamber through a plurality of inlet holes. The reactive species are free radicals such as oxygen radicals, fluorine radicals, and the like. These reactive species react with the unwanted residues in the process chamber and generate volatile products. The invention also provides a method for controlling the flow rate of the reactive species.

### BACKGROUND

The present invention relates to a method for cleaning a process chamber of a reactor. More specifically, the present invention relates to remote plasma cleaning of a process chamber of a chemical vapor deposition (CVD) reactor.

In the semiconductor industry, selected materials are deposited on a target substrate to produce electronic components. The various deposition techniques employed in the industry include chemical vapor deposition (CVD), plasma enhanced chemical vapor deposition (PECVD), atomic layer deposition (ALD), and the like. In the CVD process, vaporized gaseous reactants are introduced into a process chamber and result in the formation of films on the target substrate. During the deposition process, unwanted films and particulate materials accumulate on surfaces other than the target substrate. The unwanted films and particulate materials may accumulate on the walls of the process chamber, susceptor, and on other employed equipment. These unwanted films and particulate materials can change the surface characteristics of the process chamber. Further, the unwanted films and particulate materials can flake off from the walls of the process chamber and get deposited on the wafers, causing defects on their surfaces. Therefore, the process chamber needs to be cleaned at regular intervals to ensure proper functioning of the deposition process.

The unwanted films and particulate materials deposited in the process chamber can be removed by plasma cleaning. This involves reacting a reactive species with the unwanted films and particulate materials to generate volatile products. Thereafter, the volatile products are removed from the process chamber. Plasma cleaning can be of two types—remote plasma cleaning and in situ plasma cleaning. In in situ plasma cleaning, the plasma is generated inside the CVD reactor, but in remote plasma cleaning it is generated outside the CVD reactor. Remote plasma cleaning has distinct advantages over in situ plasma cleaning. For example, there is reduced CVD reactor damage, greater feed gas destruction efficiency, a shorter clean time, etc. Therefore, remote plasma cleaning is the preferred method for cleaning the process chamber of the CVD reactor. In the CVD process, the reactive species are supplied to the process chamber through holes of a shower plate. However, a large part of the reactive species formed in a remote plasma generator recombines into an inert form by the time they reach the process chamber. Therefore, a substantial portion of the reactive species is wasted, resulting in low utilization and cleaning efficiency and non-uniform cleaning. Therefore, the CVD reactor needs to be well maintained on a more regular basis in the case of low cleaning efficiency to get the desired quality of films. This results in increased downtime of the reactor.

Accordingly, there is a need for a process and an apparatus that enhances the utilization efficiency of the reactive species. The apparatus and the method should have high cleaning efficiency to clean the process chamber of the CVD reactor. Further, the apparatus and the method should feed the reactive species uniformly into the process chamber. Furthermore, the apparatus and the method should be able to control the flow rate of the reactive species.

### BRIEF SUMMARY OF THE INVENTION

An object of the present invention is to provide a process and an apparatus for efficient and uniform remote plasma cleaning of a process chamber of a chemical vapor deposition (CVD) reactor.

Another object of the present invention is to provide a process and an apparatus that enables high utilization efficiency of the reactive species.

Yet another object of the present invention is to provide a process and an apparatus that can control the flow rate of the reactive species.

To achieve the objects mentioned above, the present invention provides a process and an apparatus that includes supplying the reactive species into the process chamber of the CVD reactor through a plurality of inlet holes. The plurality of inlet holes is located on a ring-shaped first body. The reactive species are generated in a remote plasma unit and are supplied to the process chamber through a first conduit. The first conduit connects the remote plasma unit to the first body. The reactive species are introduced into the process chamber via the plurality of inlet holes. This ensures the high utilization efficiency of the reactive species and uniform cleaning of the process chamber. Further, the flow rate of the reactive species can be controlled by inserting one or more parts into one or more of the plurality of inlet holes of the first body or by changing the flow rate of a cleaning gas. The reactive species react with unwanted deposited films in the process chamber and produce volatile products that are then exhausted from the process chamber.

### BRIEF DESCRIPTION OF THE DRAWINGS

The preferred embodiments of the invention will hereinafter be described in conjunction with the appended drawings, provided to illustrate and not to limit the invention, wherein like designations denote like elements, and in which:

FIG. 1 is a cross-sectional view of a CVD apparatus that is coupled with a remote plasma unit, in accordance with a first embodiment of the invention;

FIG. 2 is a cross-sectional view of a first body, in accordance with the first embodiment of the invention;

FIG. 3 is a cross-sectional view of a CVD apparatus that is coupled with a remote plasma unit, in accordance with a second embodiment of the invention;

FIG. 4 is a perspective view of a first body, in accordance with the second embodiment of the invention;

FIG. 5 is a cross-sectional view of a CVD apparatus, in accordance with a third embodiment of the invention;

FIG. 6 is a top view of a shower plate, in accordance with the third embodiment of the invention; and

FIG. 7 is a flowchart describing a process for cleaning a process chamber of a CVD reactor, in accordance with various embodiments of the invention.

### DETAILED DESCRIPTION OF THE INVENTION

The present invention provides a process and an apparatus for uniform and efficient remote plasma cleaning of a process chamber of a chemical vapor deposition (CVD) reactor. A remote plasma unit is coupled with the CVD reactor. Reactive species are generated in the remote plasma unit and are supplied to the process chamber of the CVD reactor through a plurality of inlet holes. The plurality of inlet holes is located on a ring-shaped first body.

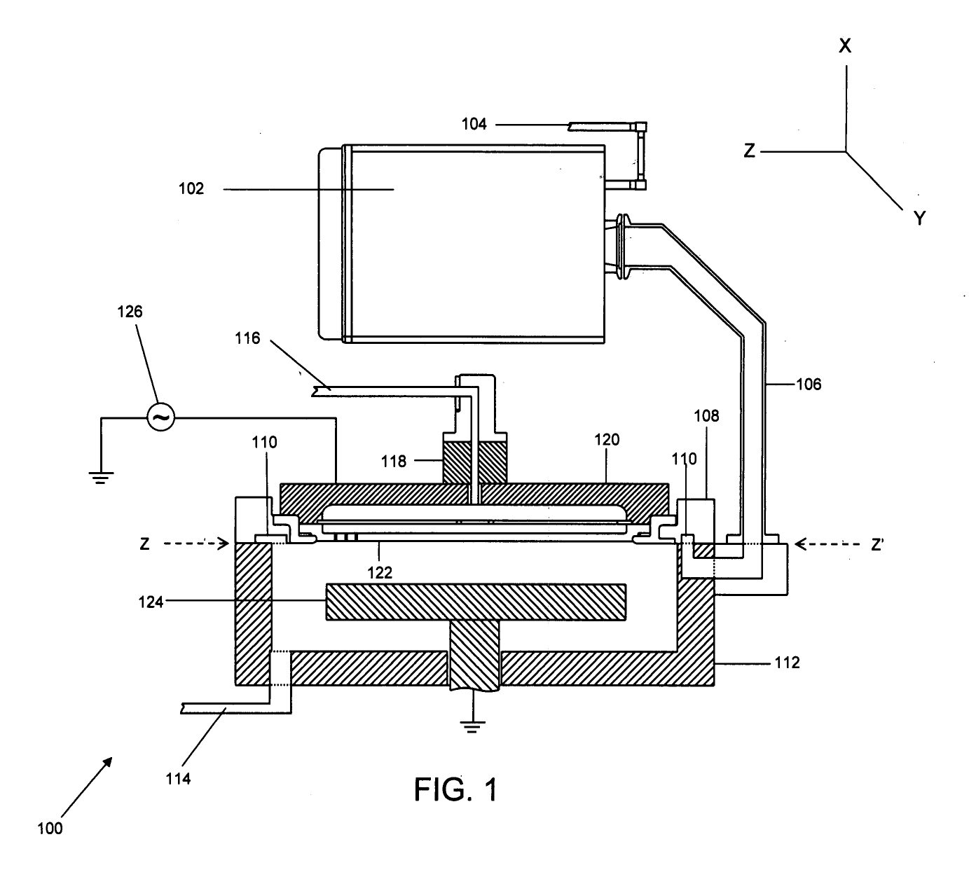

FIG. 1 is a cross-sectional view of a CVD apparatus that is coupled with a remote plasma unit, in accordance with a first embodiment of the invention. Apparatus 100 includes remote plasma unit 102, a cleaning gas inlet 104, a first conduit 106, a first body 108, a plurality of inlet holes 110, a second body 112, an exhaust line 114, a second conduit 116, an insulator 118, an upper body 120, a shower plate 122, a susceptor 124, and a radio frequency (RF) generator 126.

The reactive species used in remote plasma cleaning are free radicals and are generated in remote plasma unit 102. In various embodiments of the present invention, the reactive species may be fluorine radicals, oxygen radicals, and the like. The reactive species are generated from a cleaning gas, which is supplied to remote plasma unit 102 through cleaning gas inlet 104. In an embodiment of the invention, the cleaning gas is a mixture of oxygen, a rare gas such as Ar, and an additive gas such as N2 gas. In an embodiment of the invention, the flow rate of oxygen gas may be set at 15,000 sccm, the flow rate of Ar gas may be set at 2, 500 sccm, and the flow rate of N2 gas may be set at 800 sccm. In various embodiments of the invention, the flow rate of oxygen may be set in the range of 2,000 to 20,000 sccm, the flow rate of Ar may be set in the range of 1,000 to 15,000 sccm and the flow rate of N2 gas may be set in the range of 0 to 3,000 sccm.

In another embodiment of the invention, the cleaning gas may be a carbon- and fluorine-containing gas or a mixture of oxygen, and a carbon- and fluorine-containing gas. In various embodiment of the invention, the carbon- and fluorine-containing gas may be Tetrafluoromethane (CF4), Hexafluoroethane (C2F6), Octafluoropropane (C3F8), Octafluorocyclobutane (C4F8), Carbonyl fluoride (COF2), and the like. In another embodiment of the invention, the cleaning gas may be Nitrogen trifluoride (NF3) gas or a mixture of oxygen and Nitrogen trifluoride (NF3) gas.

The preliminary plasma is struck by introducing an inert gas into remote plasma unit 102. Thereafter, the cleaning gas is introduced into remote plasma unit 102 and the reactive species are generated from the cleaning gas. In an embodiment of the present invention, the inert gas may be argon, and plasma is struck by an inductively coupled plasma (ICP) source. The reactive species are generated by activation of the cleaning gas molecules. In an embodiment of the present invention, the power supplied to maintain the plasma in remote plasma unit 102 may be at least 2,000 W.

The reactive species are supplied to first body 108 through first conduit 106. In an embodiment of the invention, remote plasma unit 102 has one outlet for supplying the reactive species. First conduit 106 connects remote plasma unit 102 to first body 108. In an embodiment of the present invention, first body 108 is a ring-shaped body. First body 108 has a plurality of inlet holes 110 for supplying the reactive species to the process chamber. In accordance with the first embodiment of the invention, first conduit 106 connects remote plasma unit 102 to first body 108 through second body 112. First body 108 is detachably mounted onto second body 112. Second body 112 provides a casing for the vacuum process chamber.

The reactive species react with the unwanted residue in the process chamber and generate volatile products. These volatile products are exhausted from the process chamber by exhaust line 114. The pressure inside the CVD reactor may be set in accordance with the area that is to be cleaned. In an embodiment of the invention, the pressure inside the CVD reactor is 533 Pa and the cleaning rate is greater than 1000 nm/minute. In various embodiments of the invention, the pressure inside the CVD reactor is in the range of 100 to 1300 Pa.

Second conduit 116 supplies a process gas to the process chamber. In an embodiment of the invention, the process gas is a hydrocarbon like cyclopentene and is supplied to the reactor at a rate of about 350 sccm. In this embodiment, additive gases may be Argon and Helium gas and are supplied to the reactor at a rate of 1,700 sccm and 1,300 sccm respectively. As a result, a carbon film is formed on a substrate. Insulator 118 is attached to upper body 120 to prevent RF transfer from the process chamber. Insulator 118 is made of ceramic material. Upper body 120 is placed over second body 112. Thus, second conduit 116 supplies process gas to the process chamber through upper body 120. The process gas is introduced into the process chamber through a plurality of holes of shower plate 122. In an embodiment of the invention, the size (diameter) of shower plate 122 is 0.350 mm and is set at a temperature range of 100 to 200 centigrade. The process chamber has susceptor 124 for holding a substrate. In an embodiment of the invention, the size (diameter) of the substrate is 0.300 mm and the distance between shower plate 122 and susceptor 124 is in the range of 1 to 50 mm. In various embodiment of the invention, susceptor 124 may be set at a temperature range of 150 to 600 centigrade. Radio frequency generator 126 provides power for generating plasma from the process gas. Radio frequency generator 126 is integrated with the process chamber.

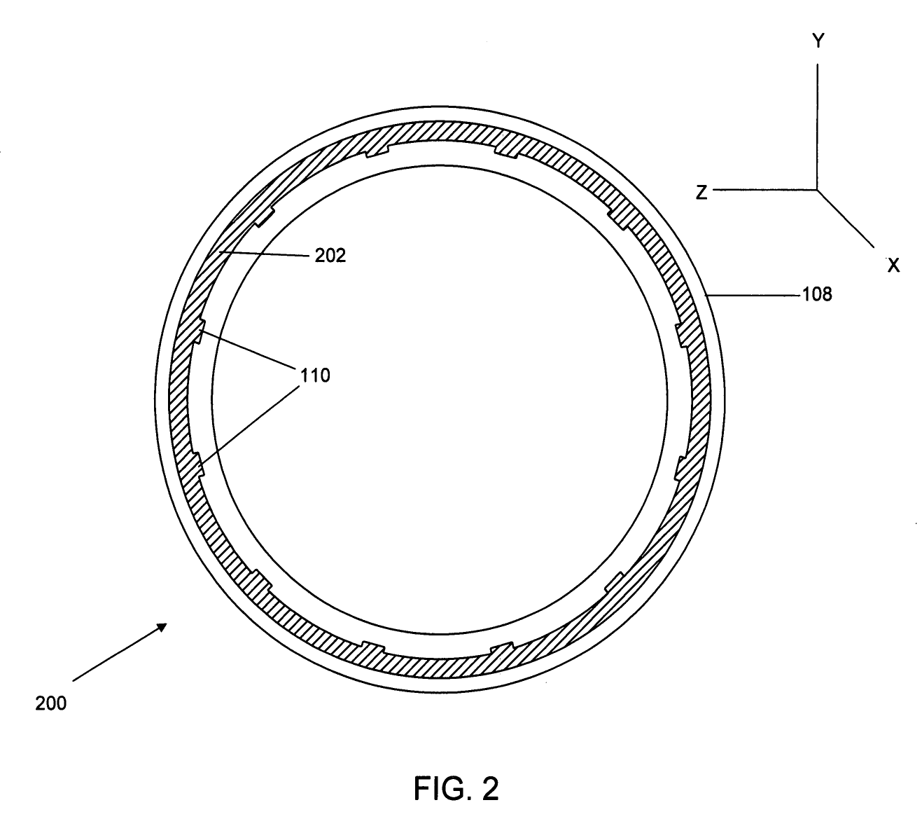

FIG. 2 is a cross-sectional view of a first body, along the arrow line labeled Z-Z′ of the first body 108, in accordance with the first embodiment of the invention. FIG. 2 includes first body 108, a groove 202, and plurality of inlet holes 110. First body 108 has ring-shaped groove 202. The reactive species flow circumferentially through groove 202 and are introduced into the process chamber through the plurality of inlet holes 110. The flow of the reactive species can be controlled by inserting one or more parts into one or more of the plurality of inlet holes 110. In an embodiment of the invention, the one or more parts are metallic. In another embodiment of the invention, the one or more parts are made of a ceramic material. One or more parts may be inserted into one or more of the plurality of inlet holes 110, and one or more of the plurality of inlet holes 110 may be kept open, in accordance with the area that is to be cleaned. Therefore, the flow rate of the reactive species can be controlled independently across the plurality of inlet holes 110 in accordance with the area that is to be cleaned.

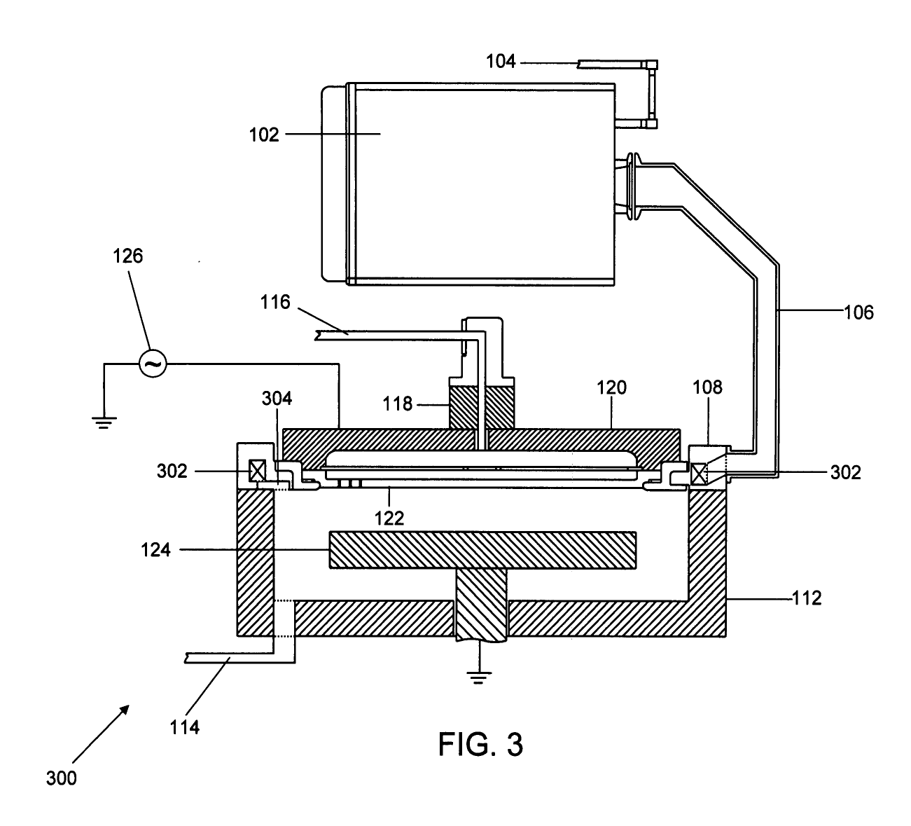

FIG. 3 is a cross-sectional view of a CVD apparatus that is coupled with a remote plasma unit in accordance with a second embodiment of the invention. FIG. 3 includes remote plasma unit 102, cleaning gas inlet 104, first conduit 106, first body 108, a tunnel 302, a plurality of inlet holes 304, second body 112, exhaust line 114, second conduit 116, insulator 118, upper body 120, shower plate 122, susceptor 124, and radio frequency (RF) generator 126.

In accordance with the second embodiment of the invention, first conduit 106 is connected to an upper part of first body 108 directly and not through second body 112. The process chamber can be cleaned in accordance with the second embodiment of the invention under the process conditions as described in the first embodiment of the invention.

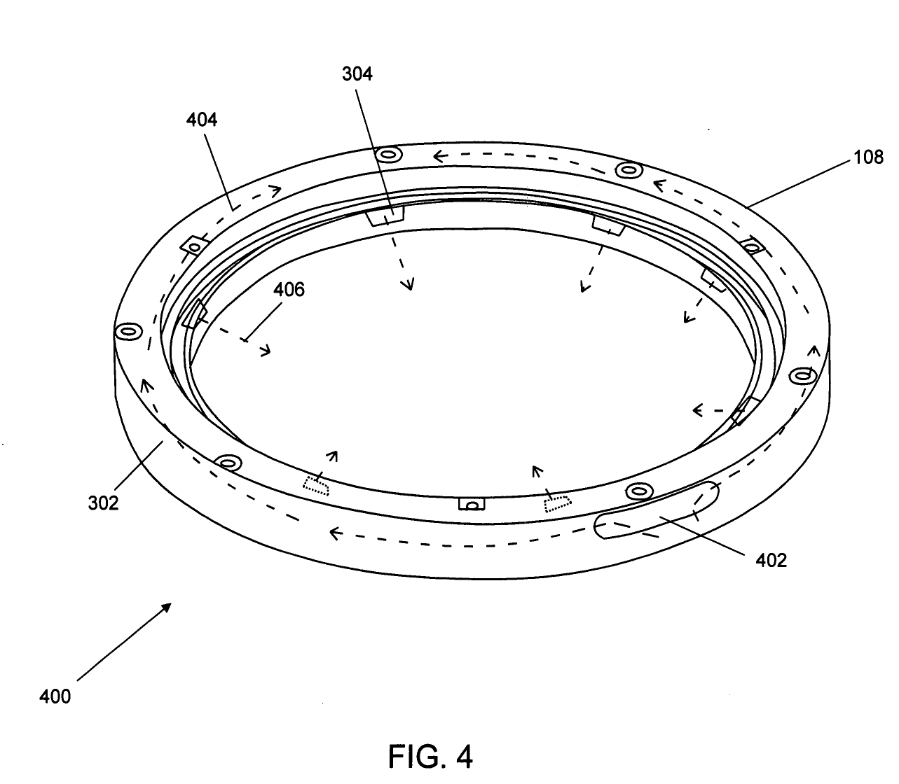

FIG. 4 is a perspective view of a first body in accordance with the second embodiment of the invention. FIG. 4 includes first body 108, an inlet 402, tunnel 302 and the plurality of inlet holes 304. First body 108 has the plurality of inlet holes 304 for supplying the reactive species into the process chamber. The reactive species are moved circumferentially through tunnel 302 as indicated by the arrows 404. First conduit 106 supplies the reactive species into tunnel 302 through inlet 402. Arrows 406 depict the direction of flow of the reactive species from first body 108 into the process chamber.

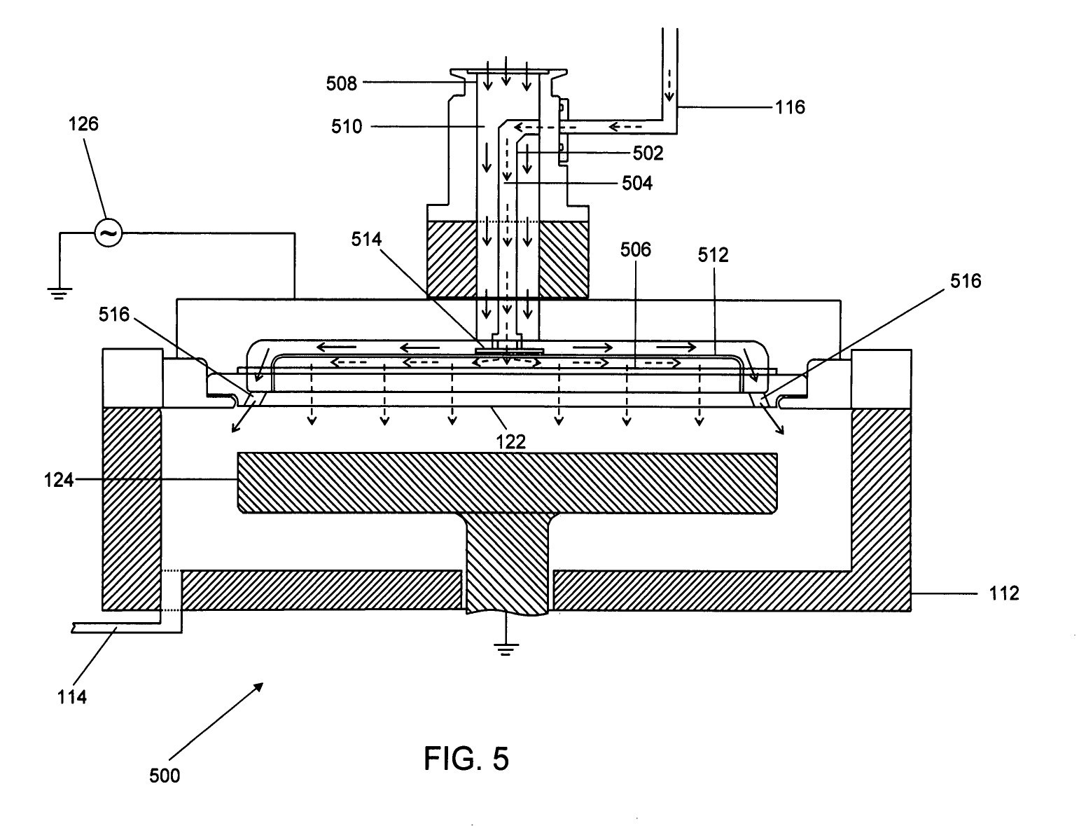

FIG. 5 is a cross-sectional view of a CVD apparatus in accordance with the third embodiment of the invention. FIG. 5 includes second body 112, exhaust line 114, second conduit 116, shower plate 122, susceptor 124, RF generator 126, an inner pipe 502, a vertical passage 504 of the inner pipe, a first plate 506, an outer pipe 508, a vertical passage 510 of the outer pipe, a second plate 512, a third plate 514, and a plurality of inlet holes 516.

Second conduit 116 supplies the process gas to inner pipe 502. The process gas is supplied through the vertical passage 504 of inner pipe 502 to first plate 506. First plate 506 distributes the process gas uniformly to shower plate 122. Shower plate 122 supplies the process gas to the process chamber. The reactive species are supplied through outer pipe 508 and pass through the vertical passage 510 of the outer pipe 508. Second plate 512 changes the direction of the flow of the reactive species and is attached to the upper portion of first plate 506. The reactive species generate heat at the contact point between second plate 512 and inner pipe 502. Therefore, third plate 514 is mounted on second plate 512 to prevent heat breakage of second plate 512. Inner pipe 502, second plate 512 and third plate 514 are made of a metal or a ceramic material. In an embodiment of the invention, the ceramic material may include aluminum nitride (AlN) ceramics, aluminum oxide (AL₂O₃) ceramics, sapphire glass, and the like. The reactive species are introduced into the process chamber through plurality of inlet holes 516.

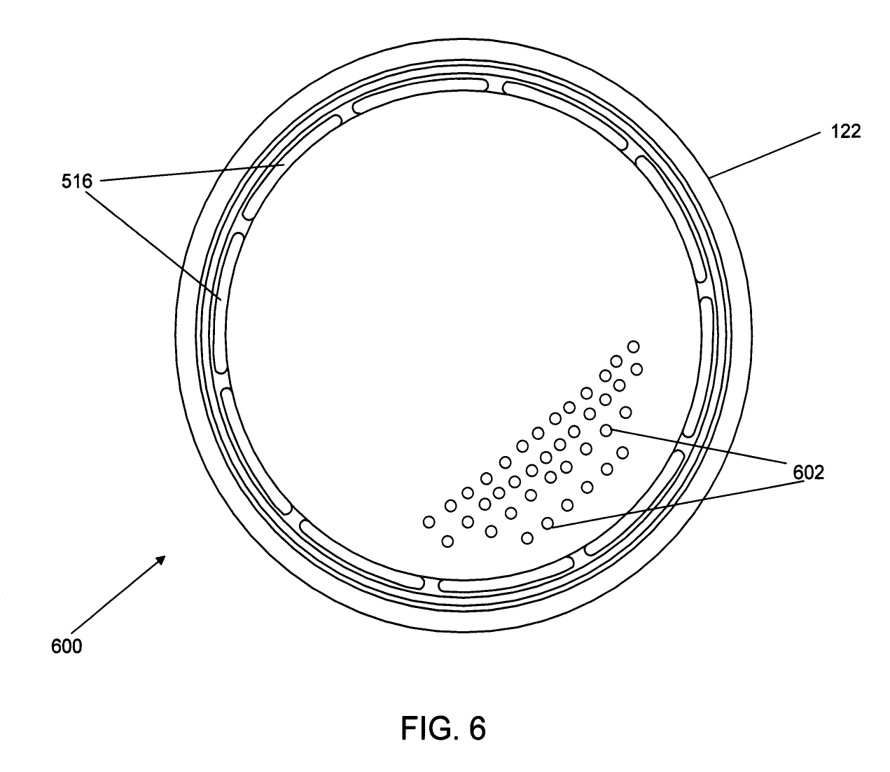

FIG. 6 is a top view of a shower plate in accordance with the third embodiment of the invention. FIG. 6 includes shower plate 122 having the plurality of inlet holes 516, and the plurality of shower-head holes 602. The reactive species are introduced into the process chamber through the plurality of inlet holes 516. The process gas is introduced into the process chamber through the plurality of shower-head holes 602. In an embodiment of the invention, the inlet holes 516 are oval-shaped, and the shower-head holes 602 are small circle-shaped. In various embodiment of the invention, the diameter of the shower head holes is in the range of is 0.1 to 5.0 mm. In accordance with an embodiment of the invention, the flow rate of the reactive species is controlled by changing the flow rate of the cleaning gas.

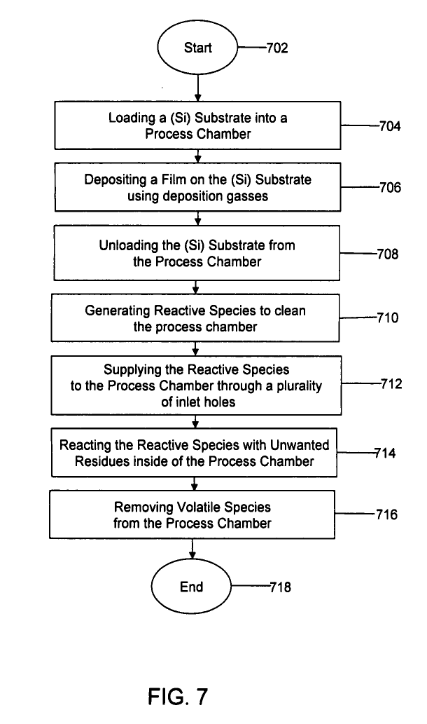

FIG. 7 is a flowchart describing a process for cleaning a process chamber of a CVD reactor, in accordance with various embodiments of the invention. FIG. 7 includes steps 702, 704, 706, 708, 710, 712, 714, 716 and 718.

The process starts at step 702. A substrate such as silicon is loaded into the process chamber at step 704. At step 706, a film such as carbon-based film is deposited on the silicon substrate in the process chamber. In an embodiment of the invention, the process gas is a hydrocarbon like cyclopentene and is supplied to the reactor at a rate of about 350 sccm. In this embodiment, additive gases may be Argon and Helium gas and are supplied to the reactor at a rate of 1,700 sccm and 1,300 sccm respectively. A conduit supplies the process gas to the process chamber through an upper body. The process gas is introduced into the process chamber through the plurality of holes of a shower plate. In an embodiment of the invention, the size (diameter) of the shower plate is 0.350 mm and is set at a temperature range of 100 to 200 centigrade. The process chamber has a susceptor for holding a substrate. In an embodiment of the invention, the size (diameter) of the substrate is 0.300 mm and the distance between the shower plate and the susceptor is in the range of 1 to 50 mm. Further, the susceptor may be set at a temperature range of 200 to 600 centigrade.

The silicon substrate is unloaded from the process chamber at step 708 after the carbon film is deposited on it. At step 710, the reactive species are generated in a remote plasma unit in order to remove the unwanted residues inside of the process chamber. In various embodiments of the present invention, the reactive species may be fluorine radicals, oxygen radicals, and mixture thereof. The preliminary plasma is struck by introducing an inert gas into a remote plasma unit. Thereafter, a cleaning gas such as oxygen is introduced into the remote plasma unit and the reactive species are generated from the cleaning gas. In an embodiment of the present invention, the inert gas may be argon, and plasma is struck by an inductively coupled plasma (ICP) source. The reactive species are generated by activation of the cleaning gas molecules. In an embodiment of the present invention, the power supplied to maintain the plasma in remote plasma unit 102 may be at least 2,000 W.

At step 712, the reactive species are supplied to the process chamber through a first body. A first conduit connects the remote plasma unit to the first body. The first body has a plurality of inlet holes. The reactive species are supplied to the process chamber through the plurality of inlet holes. The flow of the reactive species can be controlled. In an embodiment of the invention, the flow rate of the reactive species is controlled by inserting one or more parts into one or more of the plurality of inlet holes. In another embodiment of the invention, the flow rate of the reactive species is controlled by changing the flow rate of the cleaning gas. In an embodiment of the invention, the one or more parts are metallic parts. In another embodiment of the invention, the one or more parts are made of a ceramic material. Further, the flow rate of the reactive species can be controlled independently across the plurality of inlet holes in accordance with the area that is to be cleaned. That is, one or more parts may be inserted into one or more of the plurality of inlet holes 110, and one or more of the plurality of inlet holes 110 may be kept open, in accordance with the area that is to be cleaned.

At step 714, the reactive species react with the unwanted residues in the process chamber. These unwanted residues are formed in the process chamber during the film-deposition process. The reactive species react with the unwanted residues and generate volatile products. The volatile products are removed from the process chamber at step 716 using an exhaust line. The process ends at step 718.

The remote plasma cleaning process and apparatus of the present invention enable high-utilization efficiency of the reactive species. The uniform distribution of the reactive species ensures high cleaning efficiency. Further, the remote plasma cleaning process of the present invention can control the flow rate of the reactive species. Control over the flow rate of the reactive species makes the process suitable for the use of radicals such as oxygen radicals, NF3 radicals and the like as the reactive species.

While the preferred embodiments of the invention have been illustrated and described, it will be clear that the invention is not limited to these embodiments only. Numerous modifications, changes, variations, substitutions and equivalents will be apparent to those skilled in the art, without departing from the spirit and scope of the invention, as described in the claims.

What is claimed is:

1. An apparatus for cleaning a process chamber, the apparatus comprising:
i. a remote plasma unit with at least one outlet, the remote plasma unit generating reactive species and supplying the reactive species through the at least one outlet;
ii. a first body with a plurality of inlet holes, the plurality of inlet holes being formed circumferentially around the first body, the plurality of inlet holes introducing the reactive species into the process chamber; and
iii. a first conduit, the first conduit connecting the remote plasma unit to the first body.

2. The apparatus according to the claim 1, wherein the process chamber is a chemical vapor deposition (CVD) reactor process chamber.

3. The apparatus according to claim 1 further comprising a second body, the second body surrounding the process chamber.

4. The apparatus according to claim 1 further comprising a susceptor, the susceptor capable of holding a substrate in the process chamber, the susceptor being located inside the process chamber.

5. The apparatus according to claim 3, wherein the first body is detachably mounted on an upper part of the second body.

6. The apparatus according to claim 3, wherein the first conduit is connected to the first body through the second body.

7. The apparatus according to claim 1, wherein the first conduit is connected to an upper part of the first body.

8. The apparatus according to claim 1, wherein the first body is a ring shaped body.

9. The apparatus according to claim 8, wherein the plurality of inlet holes is formed circumferentially on the ring shaped body.

10. The apparatus according to claim 1, wherein one or more parts are inserted into one or more of the plurality of inlet holes to control the flow rate of the reactive species.

11. The apparatus according to claim 1 further comprising a second conduit, the second conduit supplying a process gas to the process chamber, the second conduit being connected to an upper part of the process chamber.

12. The apparatus according to claim 11, wherein the second conduit comprises an inner pipe, the inner pipe connecting the second conduit to the process chamber, the inner pipe being connected to the process chamber through a first plate, the first plate being connected to the process chamber through the first body.

13. The apparatus according to claim 12, wherein a second plate is attached to an upper part of the first plate, the second plate changing the direction of flow of the reactive species.

14. The apparatus according to claim 13, wherein a third plate is mounted on the second plate, the third plate being mounted on the second plate to prevent a heat breakage of the second plate.

15. The apparatus according to claim 1, wherein the first body includes a shower plate, the plurality of inlet holes being formed circumferentially around a periphery of the shower plate.

16. The apparatus according to claim 1, wherein the plurality of inlet holes is oval shaped.

17. A process for cleaning a process chamber, the process comprising the steps of:
i. generating reactive species in a remote plasma unit;
ii. supplying the reactive species through at least one outlet of the remote plasma unit;
iii. introducing the reactive species into the process chamber through a plurality of inlet holes of a first body, the plurality of inlet holes formed circumferentially around the first body, the first body being connected to the remote plasma unit through a first conduit;
iv. reacting the reactive species with residues in the process chamber and generating volatile products; and
v. removing the volatile products from the process chamber.

18. The process according to claim 17 further comprising supplying a process gas to the process chamber through a second conduit, the second conduit being attached to an upper part of the process chamber.

19. The process according to claim 17 further comprising controlling the flow rate of the reactive species.

20. The process according to claim 19, wherein the flow rate of the reactive species is controlled by inserting one or more parts into one or more of the plurality of inlet holes of the first body.

21. The process according to claim 19, wherein the flow rate of the reactive species is controlled by changing the flow rate of a supply gas.

22. The process according to claim 17, wherein the reactive species are oxygen radicals.

23. The process according to claim 17, wherein the reactive species are fluorine radicals.

24. The process according to claim 17, wherein the reactive species are a mixture of oxygen and fluorine radicals.

25. A method for processing a substrate, the method comprising the steps of:
i. depositing a film on a substrate in a process chamber;
ii. unloading the substrate from the process chamber
iii. generating reactive species in a remote plasma unit;
iv. supplying the reactive species through at least one outlet of the remote plasma unit;
v. introducing the reactive species into the process chamber through a plurality of inlet holes of a first body, the plurality of inlet holes formed circumferentially around the first body, the first body being connected to the remote plasma unit through a first conduit; and
vi. removing residues from the process chamber, the residues being accumulated during the deposition of the film.
